(19) United States
(12) Patent Application Publication
(10) Pub. No.: US 2018/0196763 A1
(43) Pub. Date: Jul. 12, 2018

(54) FLEXIBLE HIGH-DENSITY MEMORY MODULE

(71) Applicant: Hany Mohamed Fahmy, Bertem (BE)

(72) Inventor: Hany Mohamed Fahmy, Bertem (BE)

(21) Appl. No.: 15/869,014

(22) Filed: Jan. 11, 2018

Related U.S. Application Data
(60) Provisional application No. 62/445,597, filed on Jan. 12, 2017.

(51) Int. Cl. G06F 13/16; G11C 5/04; G11C 5/06

(52) U.S. Cl. CPC G06F 13/1668; G11C 5/06; G11C 5/04

(57) ABSTRACT

A flexible high-density memory module for use with an electronic computing device includes an interposer and a controller supported on a first substrate, a number of SDRAM modules operably arranged on a second substrate and a flexible substrate forming an electrical connection between the interposer supported on the first substrate and the SDRAM modules supported on the second substrate. The controller and the interposer supported on the first substrate is configured to electrically connect with a number of processor interconnects supported on the main rigid printed circuit board of the electronic computing device to provide a number of plug and play, flexible, high density memory channels of desired capacities utilizing the SDRAM modules supported on the second substrate. The flexible substrate enables parallel, perpendicular and angular placement of the SDRAM modules over a plane of the main rigid printed circuit board, enabling optimal routing and performance.

### CROSS-REFERENCE TO RELATED APPLICATION

The present application is related to and claims priority from prior provisional application Ser. No. 62/445,597, filed Jan. 12, 2017 which application is incorporated herein by reference.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. 37 CFR 1.71(d).

### BACKGROUND OF THE INVENTION

The following includes information that may be useful in understanding the present invention(s). It is not an admission that any of the information provided herein is prior art, or material, to the presently described or claimed inventions, or that any publication or document that is specifically or implicitly referenced is prior art.

### 1. Field of the Invention

The present invention relates generally to flexible high-density memory modules. More specifically, the present invention relates to a flexible high-density memory module with a number of high-density memory modules supported on a rigid substrate positioned away from a main circuit board of embedded computing devices.

### 2. Description of the Related Art

The miniaturization of hardware forces the engineers to use the highest performance setting for every component placed on a compact printed circuit board with minimal power consumption. Unfortunately the standard of low power low voltage technology used in the modern printed circuit board designs increase the problem related to signal and power integrity. Actually a DDR4 and LPDDR4 memory modules can run at the maxim rate of 3.2 GT/s. This kind of memory is often found in most common devices that we use in our day-to-day life. Most of the existing companies have as one main target, which is to produce high-speed devices and, at the same time, with lower consumption, lower dimension and lower prize. Embedded systems such as SBCs, ADAS and infotainment systems adopt memory-down as the sole architecture for memory channels such as DDR3, DDR4 and LPDDR4. This has the advantage of improved signal integrity and a compact design compared to using DIMM sockets. However, such memory-down architecture consumes large space or real estate on the PCB, especially when high-density memory, such as with 36-sdrams, is required. The memory devices with conventional memory-down architecture consume more than 30% of PCB surface area. This provides a challenge to route other signals such as SERDES channels through the PCB without increasing the layer-count and at the same time meeting the cost and performance targets. In addition, in designing such a system, the performance of the DDR4 and LPDDR4 high density SDRAMs to be installed on the circuit boards of such systems cannot be compromised.

Prior attempts have been made to provide high density SDRAMs that occupies less space in the main PCB. Traditional SDRAM dual inline memory modules (DIMMs) are simply too tall to be able to be mounted vertically on the system board. Special sockets have been designed to allow DIMMs to be mounted either at an angle or even parallel to the system board. As the speed of memory devices increases to greater than 200 megahertz, for example, the electrical performance of such DIMM sockets is becoming inadequate. Further the placement of DIMM sockets on the main PCB poses serious challenge to the embedded designers to route other signals such as SERDES channels through the PCB without increasing the layer-count and at the same time meeting the cost and performance targets. The following prior arts are hereby incorporated by reference for their supportive teachings of the present invention.

U.S. Pat. No. 6,545,895 titled “High capacity SDRAM memory module with stacked printed circuit boards” issued to High Connection Density, Inc. discloses a family of memory modules with granularity, upgradability, and a capacity of two gigabytes uses 256 MB SDRAM or DDR SDRAM memory devices in CSPs in a volume of just 4.54 inches by 2.83 inches by 0.39 inch. Each module includes an impedance-controlled substrate having contact pads, memory devices, and other components, including optional driver line terminators, on its surfaces. The inclusion of spaced, multiple area array interconnections allows memory devices to be symmetrically mounted on each side of each of the area array interconnections, thereby reducing the interconnect lengths and facilitating the matching of interconnect lengths. Short area array interconnections, including BGA, PGA, and LGA options or interchangeable alternative connectors provide interconnections between the modules and the rest of the system. Thermal control structures may be included to maintain the memory devices within a reliable range of operating temperatures.

Another prior art, U.S. Pat. No. 7,379,316 titled “Methods and apparatus of stacking DRAMs” issued to Metaram, Inc. discloses a memory device for electrical connection to a memory bus, the memory device comprises a number of dynamic random access memory (“DRAM”) integrated circuits, stacked in a vertical direction, each DRAM integrated circuit comprising a memory core of a number of cells and accessible at a first speed and an interface integrated circuit electrically coupled to the number of DRAM integrated circuits for providing an interface between the DRAM integrated circuits and the memory bus at a speed greater than the first speed. The interface integrated circuit is adapted for providing a predetermined electrical load on the memory bus independent of a number of the DRAM integrated circuits to which the interface integrated circuit is electrically coupled. The stacked memory chips are constructed in such a way that eliminates problems like signal integrity while still meeting current and future memory standards. However, the above prior art fails to assist the embedded designers to design a compact main circuit board with plug and play high density memory channels for many embedded computing systems.

Yet another prior art, U.S. Pat. App. No. 20110149499 A1 titled “DIMM Riser Card With An Angled DIMM Socket And A Straddled Mount DIMM Socket” filed by International Business Machines Corporation discloses a DIMM riser card that includes a PCB having a first edge, a second edge, and one or more faces. The first edge of the PCB is configured for insertion into a main board DIMM socket. The first edge includes electrical traces that electrically couple to a memory bus. The DIMM riser card includes an angled DIMM socket mounted on one face of the PCB, where the angled DIMM socket is configured to accept a DIMM at an angle not perpendicular to the PCB and electrically couple the DIMM to the memory bus. The DIMM riser card includes a straddle mount DIMM socket mounted on the second edge of the PCB. The straddle mount DIMM socket is configured to accept a DIMM and electrically couple the DIMM to the memory bus through the electrical traces on the first edge of the PCB. However, the above prior art fails to assist the embedded designers to design a compact main circuit board with plug and play high density memory channels for many embedded computing systems.

Hence there exists a need for a plug and play, flexible high-speed memory module that can be placed with different configuration on a main circuit board to save the surface area of the main circuit board in many embedded systems. The needed plug and play, flexible high-speed memory module would be able to support the traditional memory-down approach and other architectures. Further the needed plug and play, flexible high-speed memory module would assist in the optimized routing of the memory channels, and other high speed SerDes on a main PCB of an embedded system and would also provide improved signal integrity for those signals. Furthermore, the needed plug and play, flexible high-speed memory module would allow the designers to place the DIMMs in various positions, which would allows the designers to optimally design thermal management and mechanical enclosures to the embedded systems.

### BRIEF SUMMARY OF THE INVENTION

The present invention relates to a flexible high-density memory module for use with a number of electronic computing devices. The flexible high-density memory module includes an interposer having a number of interposer interconnects supported on a first substrate. The interposer interconnects are configured to form one or more connection with a number of processor interconnects supported on a main rigid printed circuit board of the electronic computing devices. The flexible high-density memory module further includes a controller supported on the first substrate, a number of SDRAM modules operably arranged on a second substrate and one or more conductive traces supported on a flexible substrate having a first end and a second end, each having a number of connectors, for forming an electrical connection between the interposer supported on the first substrate and the SDRAM modules supported on the second substrate. The controller and the interposer supported on the first substrate is configured to electrically connect to the processor interconnects supported on the main rigid printed circuit board of the electronic computing device to provide a plug and play, flexible, high density memory channels of desired capacities utilizing the SDRAM modules supported on the second substrate.

The first substrate supporting the interposer and the controller is a first rigid printed circuit board, which supports the interposer and the controller on one side of the first rigid printed circuit board or on opposite sides. Further the second substrate supporting the SDRAM modules is a second rigid printed circuit board, which is provided with a large surface area compared to the first rigid printed circuit board for supporting the high-density arrangement of the SDRAM modules based on a memory down architecture. The flexible substrate supporting the conductive traces is a flexible printed circuit board with the number of connectors at the first end of the conductive traces connects to the interposer and the controller supported on the first substrate and the connectors at the second end of the conductive traces connects to the SDRAM modules supported on the second substrate. The controller supported on the first substrate communicates with the SDRAM modules supported on the second substrate through the conductive traces supported on the flexible substrate. The SDRAM modules supported on the second substrate forms a dual in-line memory module (DIMM) of desired capacity, capable of operating at a desired frequency. Further, the flexible high-density memory module can be used as a plug and play memory channels for the electronic computing devices. The flexible substrate enables a parallel, perpendicular or angular placement of the SDRAM modules over the main rigid printed circuit board of the electronic computing device for optimal utilization of a surface area, efficient thermal design, efficient routing of conductive traces of SERDES channels, improved heat dissipation and improved performance of the electronic computing device.

The present invention further relates to an electronic computing device having a processor having a number of processor interconnects supported on a main rigid printed circuit board, a number of conductive paths provided on the main rigid circuit board to enable connections between the processor and a number of components via the processor interconnects and a flexible high density memory module. The flexible high density memory module includes an interposer and a controller supported on a first substrate configured to form at least one connection with the processor interconnects, a number of SDRAM modules arranged on a second substrate and a flexible substrate supporting the conductive traces for forming an electrical connection between the interposer interconnects and the SDRAM modules. The processor communicates with the SDRAM modules through the conductive traces provided on the flexible substrates. The flexible substrate of the flexible high-density memory module enables a parallel, perpendicular and angular placement of the SDRAM modules arranged on the second substrate over a plane of the main rigid printed circuit board. This arrangement allows the embedded designers to optimize a surface area of the main rigid printed circuit board by placing the SDRAM modules on the second substrate over the main rigid printed circuit board. The flexible substrate, of the flexible high-density memory module, connecting the first substrate to the second substrate enables an optimal surface area utilization of the main rigid printed circuit board, an optimal heat dissipation from the SDRAM modules, an optimal performance of the SDRAM modules and an optimal routing and performance of the SERDES channels associated with the main rigid printed circuit board.

A primary feature of the invention provides a flexible high-density memory module having rigid-flex architecture for optimizing a surface area of the main PCB of an embedded computing device.

A second feature of the present invention provides a plug and play flexible high-density memory module for embedded computing devices.

A third feature of the present invention provides a flexible high-density memory module having a first rigid substrate having a small area supporting an interposer and a controller and a second rigid substrate supporting SDRAM modules and a flexible PCB connecting the first rigid substrate and a second rigid substrate.

Another feature of the present invention provides a plug and play, flexible, high-density memory channels of desired capacities that can be plugged into the main circuit board of the embedded computing devices in parallel, perpendicular or at an angle with a plane of the main circuit board.

Another feature of the present invention provides a plug and play, flexible, high-density memory channels that enable the embedded designers to design the main rigid printed circuit board of the embedded computing devices with minimum 30% savings in the surface area.

Another feature of the present invention provides a plug and play, flexible, high-density memory channels that enable the embedded designers to design optimal routing channels on the main rigid printed circuit board and to achieve optimal performance of the SERDES channels associated with the main rigid printed circuit board of the embedded computing devices.

These together with other features of the invention, along with the various features of novelty, which characterize the invention, are pointed out with particularity in the disclosure. For a better understanding of the invention, its operating advantages and the specific objects attained by its uses, reference should be had to the accompanying drawings and descriptive matter in which there are illustrated preferred embodiments of the invention. In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

### BRIEF DESCRIPTION OF THE DRAWINGS

The figures which accompany the written portion of this specification illustrate embodiments and method(s) of use for the present invention, an Improved Walking Stick, constructed and operative according to the teachings of the present invention.

FIG. 1 is a printed circuit board with an integrated high-density memory down architecture, according to a prior art of the present disclosure;

FIG. 2 illustrates a schematic showing a conventional memory down architecture of a high-density dual in line memory module (DIMM), according to a prior art of the present disclosure;

FIG. 3 is a schematic diagram showing the present flexible high-density memory module for use with a number of electronic computing devices, according to a preferred embodiment of the present disclosure;

FIG. 4 is a schematic diagram showing the present flexible high-density memory module for use with the electronic computing devices, according to an alternate embodiment of the present disclosure;

FIG. 5 is a schematic diagram showing the present flexible high-density memory module for use with the electronic computing devices, according to another alternate embodiment of the present disclosure;

FIG. 6 illustrates a microstrip test structure of a flexible substrate associated with the present flexible high-density memory module to analyze the effect of bend angle and bend radius of the flexible substrate on signal integrity and radiated emission from the present flexible high-density memory module, according to an embodiment of the present disclosure;

FIG. 7 is a graph showing an insertion loss of the present flexible high-density memory module for different bend angles of the flexible substrate under a constant bend radius, according to an embodiment of the present invention;

FIG. 8 is a graph showing an insertion loss of the present flexible high-density memory module for different bend radii of the flexible substrate under a constant bend angle, according to an embodiment of the present invention;

FIG. 9 is a graph showing a normalized radiated emission at a distance for different bend angles of the flexible substrate, according to an embodiment of the present invention;

FIG. 10 is a graph showing a normalized radiated emission at a distance for different bend radii of the flexible substrate, according to an embodiment of the present invention;

FIG. 11A shows a three-dimensional model of the present flexible high-density memory module, according to a preferred embodiment of the present invention;

FIG. 11B shows the first substrate supporting the interposer and the controller, solder balls, interposer, the flexible substrate and the second substrate supporting the SDRAM modules are represented without simplifications in full 3D detail, according to an embodiment of the present invention;

FIG. 12 shows a three-dimensional model showing a breakout region of the main rigid printed circuit board and an interposer of the flexible high-density memory module, according to a preferred embodiment of the present invention;

FIG. 13 shows a worst-case eye diagram and BER contour for one victim on the Flex-DIMM at 2666 MT/s without considering the crosstalk, according to an embodiment of the present invention;

FIG. 14 shows a worst-case eye diagram and BER contour for one victim on a Reference Design at 2666 MT/s without considering the crosstalk, according to an embodiment of the present invention;

FIG. 15A shows an insertion loss and far-end crosstalk for one bit of the reference design and the same bit on the flex interposer of the present flexible high-density memory module, according to an embodiment of the present invention; and

FIG. 15B shows an insertion loss and far-end crosstalk for one bit on the flex interposer of the present flexible high-density memory module, according to an embodiment of the present invention.

### DETAILED DESCRIPTION

In the following discussion that addresses a number of embodiments and applications of the present invention, reference is made to the accompanying drawings that form a part hereof, and in which is shown by way of illustration specific embodiments in which the invention may be practiced. It is to be understood that other embodiments may be utilized, and changes may be made without departing from the scope of the present invention. The embodiments of the present disclosure described below are not intended to be exhaustive or to limit the disclosure to the precise forms disclosed in the following detailed description. Rather, the embodiments are chosen and described so that others skilled in the art may appreciate and understand the principles and practices of the present disclosure.

Further, various inventive features are described below that can each be used independently of one another or in combination with other features. However, any single inventive feature may not address any of the problems discussed above or only address one of the problems discussed above. Further, one or more of the problems discussed above may not be fully addressed by any of the features described below. The following embodiments and the accompanying drawings, which are incorporated into and form part of this disclosure, illustrate one or more embodiment of the invention and together with the description, serve to explain the principles of the invention. To the accomplishment of the foregoing and related ends, certain illustrative aspects of the invention are described herein in connection with the following description and the annexed drawings. These aspects are indicative, however, of but a few of the various ways in which the principles of the invention can be employed and the subject invention is intended to include all such aspects and their equivalents. Other advantages and novel features of the invention will become apparent from the following detailed description of the invention when considered in conjunction with the drawings.

Further the following section summarizes some aspects of the present disclosure and briefly introduces some preferred embodiments. Simplifications or omissions in this section as well as in the abstract or the title of this description may be made to avoid obscuring the purpose of this section, the abstract and the title. Such simplifications or omissions are not intended to limit the scope of the present disclosure nor imply any limitations.

The present invention relates to flexible high-density memory modules for use with a variety of electronic computing devices such as, but not limited to, single board computers (SBCs), advanced driver assistance systems (ADAS), infotainment systems and other embedded systems utilizing a single board system having a hardware package and an embedded software package employed in a number of industries. In addition, the present flexible high-density memory modules are designed for use with many embedded computing systems used for specialized purposes such as high-performance computing. The present flexible high-density memory modules enable efficient space utilization in the main circuit board of the embedded computing systems. Further the present flexible high-density memory modules provide optimal performance of the memory modules along with minimal power consumption compared to the existing memory modules utilizing the memory down architecture. The present flexible high-density memory modules enable the designers to free up an additional surface area of 30% or more on the conventional main circuit boards with efficient placement of the high performance memory modules over the main circuit boards. Further, the present arrangement of the flexible high-density memory modules enables the designers to effectively design the conductive traces for the other signals such as a Serializer-Deserializer (SERDES) including PCIE-gen3, Ethernet 10GBASE-KR, SATA- III, USB3, etc. to route through the printed circuit board (PCB) without increasing the layer-count to meet the cost-target of the PCB and performance of these signals at the same time.

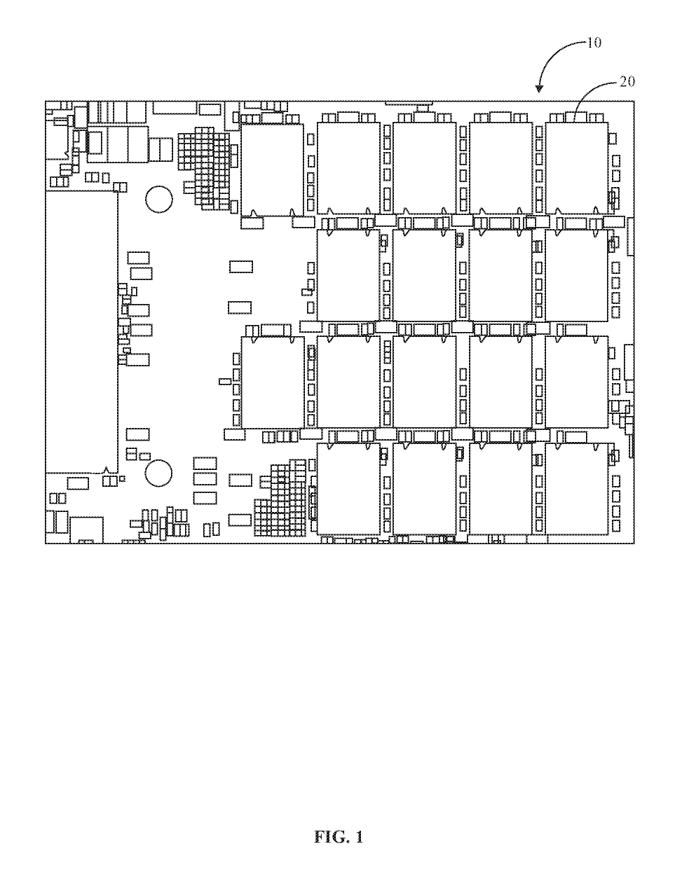

FIG. 1 shows an exemplary printed circuit board 10 with an integrated high-density memory channel 20 in a high-density memory-down configuration, according to a prior art of the present disclosure. The printed circuit board 10 of the prior art forms an exemplary board design of a variety of embedded computing systems such as embedded computers used for a variety of applications, such as but not limited to, high performance computing, advanced driver assistance systems, infotainment systems, etc. Modern computers and other embedded computing systems utilize the high-density memory 20 in a memory-down configuration to increase the memory capacity and density of the memory modules on the printed circuit board 10. Some embedded systems utilize the traditional SDRAM dual in-line memory modules (DIMMs) 20 to achieve high-density and capacity of the memory modules. FIG. 1 shows an example of double data rate fourth generation (DDR4) high-density memory channels with 36-SDRAMs 20 on the PCB 10 of an embedded computing system. The DDR4 SDRAMs 20 consumes more than 30% of the real-estate on the PCB 10 leaving hard chance for other signals such as SERDES, including PCIE-gen3, Ethernet 10GBASE-KR, SATA-III, USB3, to route through the PCB 10 without increasing the layer-count to meet the cost-target of the PCB 10 and performance of these signals at the same time. In addition, the space requirement for the placement of the traditional SDRAM dual in-line memory modules 20 on the main printed circuit board 10 restricts the designers from optimally designing the other components such as the SERDES including PCIE-gen3, Ethernet 10GBASE-KR, SATA- III, USB3, etc., within the limited real-estate of the main printed circuit board 10. This affects the overall cost versus performance of the embedded computing systems. In some conventional double layer PCB designs, the designers optimize the performance of the embedded computing systems by routing the conductive traces for the SERDES through the PCB 10 by increasing the layer-count and surface area of the PCB 10. The designers has to further take into account the factors such as the cost-target of the PCB 10 and performance of these signals at the same time while designing the main printed circuit board 10 of these modern embedded computing systems.

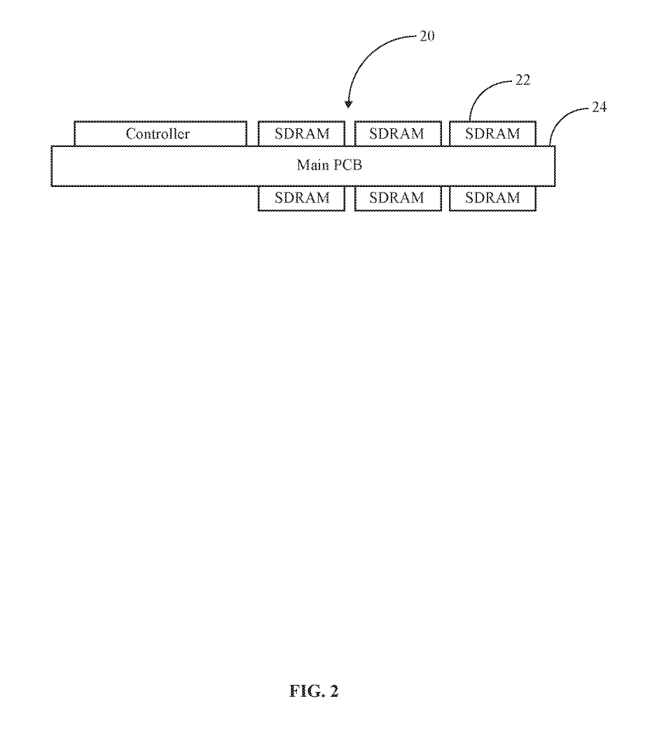

FIG. 2 illustrates a schematic showing a conventional memory-down configuration of a high-density dual in line memory module (DIMM) 20, according to a prior art of the present disclosure. The conventional memory-down configuration of the high-density dual in-line memory module (DIMM) 20 includes arrangement of a number of SDRAM modules 22 on a pair of sides of a rigid printed circuit board 24 with a controller 26 on one side for communicating with the processor of the embedded computing systems. The rigid printed circuit board 24 with the SDRAM modules 22 arranged in the conventional memory-down configuration to form the high-density dual in-line memory module 20 is configured to fit into the slots provided on the main printed circuit boards of the embedded computing systems and the PCBs of other conventional computers. The above conventional arrangement of the SDRAM modules 22 in the conventional memory-down configuration limits the capacity of the plug and play high-density dual in-line memory module 20, as the size of the rigid printed circuit board 24 cannot be increased beyond the preset standards. In some conventional main printed circuit board designs, special sockets are provided to allow DIMMs to be mounted vertically, or at an angle or even parallel to the system board. In addition, with this arrangement of the DIMMs, as the speed of memory devices increases the electrical performance of such DIMM sockets becomes inadequate. Furthermore, the elongated DIMM sockets provided on the main printed circuit boards provides almost no room for routing the conductive traces for the SERDES through the PCB. Hence, in order to optimally design the conductive traces for the SERDES through the PCB, the size of the PCB is increased, which in turn affects the overall cost of the PCB and in turn the embedded computing device utilizing the PCB.

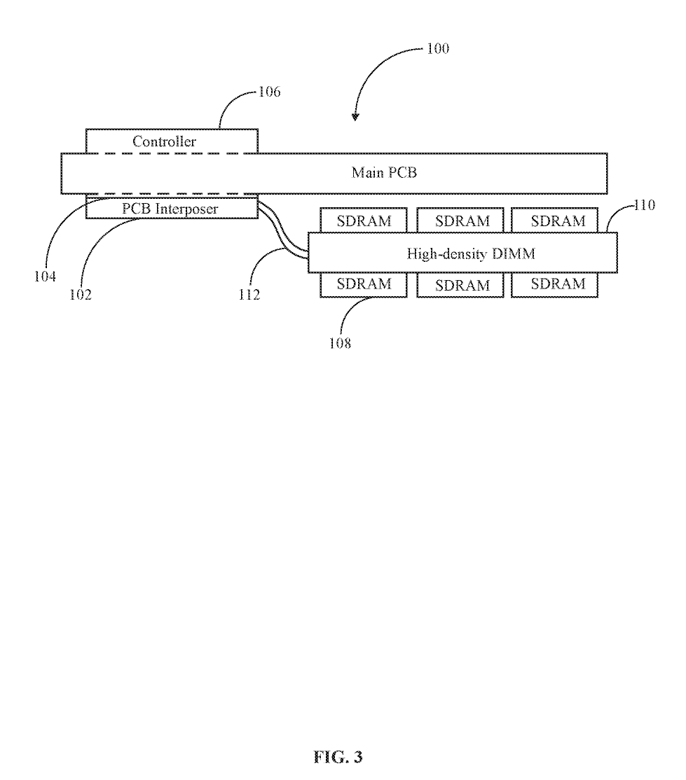

FIG. 3 is a schematic diagram showing the present flexible high-density memory module 100 for use with a number of electronic computing devices, according to a preferred embodiment of the present disclosure. The present flexible high-density memory module 100 is configured to use with a variety of electronic computing devices such as computers and other single board embedded computing systems. According to a preferred embodiment, the present flexible high-density memory module 100 includes an interposer 102 having a number of interposer interconnects supported on a first substrate 104. The interposer interconnects are configured to form a connection with a number of processor interconnects supported on a main rigid printed circuit board of the electronic computing devices. The present flexible high-density memory module 100 further includes a controller 106 supported on the first substrate 104. In some instance, the controller 106 and the interposer 102 are supported on one side of the first substrate 104. In some other instances, the controller 106 and the interposer 102 are supported on opposite sides of the first substrate 104. According to a preferred embodiment, the first substrate 104 supporting the interposer 102 and the controller 106 is a first rigid printed circuit board. The first substrate 104 supporting the interposer 102 and the controller 106 is configured to connect with the processor interconnects provided on the main rigid printed circuit board of the electronic computing devices to communicate with the processor of the electronic computing devices.

The present flexible high-density memory module 100 further includes a number of SDRAM modules 108 operably arranged on a second substrate 110. In a preferred embodiment, the second substrate 110 supporting the SDRAM modules 108 is a second rigid printed circuit board. In a preferred embodiment, the SDRAM modules 108 are arranged on the second rigid printed circuit board 110 using the high-density memory-down configuration to form a high-density dual in-line memory module (DIMM). The arrangement of the SDRAM modules 108 away from the main rigid printed circuit board, on the second substrate 110, enables the designers to provide proper heat transfer channels or ventilation for the proper cooling of the SDRAM modules 108, which in turn improves the performance of the present flexible high-density memory module 100. The controller 106 and the interposer 102 supported on the first substrate 104 is electrically connected to the SDRAM modules 108 supported on the second substrate 110 using a number of conductive traces 114 supported on a flexible substrate 112. The conductive traces 114 supported on the flexible substrate 112 includes a first end and a second end, each end having a number of connectors for forming an electrical connection between the interposer 102 supported on the first substrate 104 and the SDRAM modules 108 supported on the second substrate 110. In a preferred embodiment, the flexible substrate 112 supporting the conductive traces is a flexible printed circuit board. The connectors provided at the first end of the conductive traces 114 connects to the interposer 102 and the controller 106 supported on the first substrate 104. The connectors provided at the second end of the conductive traces 114 connects to the SDRAM modules 108 supported on the second substrate 110. Thus the flexible substrate 112 or the flexible printed circuit board connects the first rigid printed circuit board or the first substrate 104 supporting the interposer 102 and the controller 106 to the second rigid printed circuit board or the second substrate 110 supporting the SDRAM modules 108.

The controller 106 and the interposer 102 supported on the first substrate 104 is configured to electrically connect to the processor interconnects supported on the main rigid printed circuit board of the electronic computing device to provide a plug and play, flexible, high density memory channels of desired capacities utilizing the SDRAM modules 108 supported on the second substrate 110. The present flexible high-density memory module 100 is available with high performance of DDR4 and LPDDR4 high-density SDRAM modules 108, which can be utilized by the embedded computing systems to provide top-notch performance for efficient functioning of the embedded applications such as in high performance computing, SBCs, ADAS, etc. Further, the present flexible high-density memory module 100 follows a rigid-flex PCB technology with high-density high-performance DDR4 and LPDDR4 memory modules or SDRAM modules 108 supported on a separate second substrate 110, which can be easily placed parallel to and over the main rigid printed circuit board of the electronic computing devices or embedded systems, without any mechanical constraints of the connector 106, as with the conventional prior arts systems of FIG. 1 and FIG. 2. In some embodiments of the present invention, the first substrate 104 supporting the interposer 102 with the interposer interconnects is placed under the CPU/GPU/FPGA and the processor interconnectors are connected to the respective interposer interconnects, which further connects to the SDRAM modules 108 supported on the second substrate 110 using the flexible substrate 112. In some instances, the present flexible high-density memory module 100 is utilized as plug and play memory channels, which enables the embedded designers to design the main rigid printed circuit board of the electronic computing device with shortest design-cycle time.

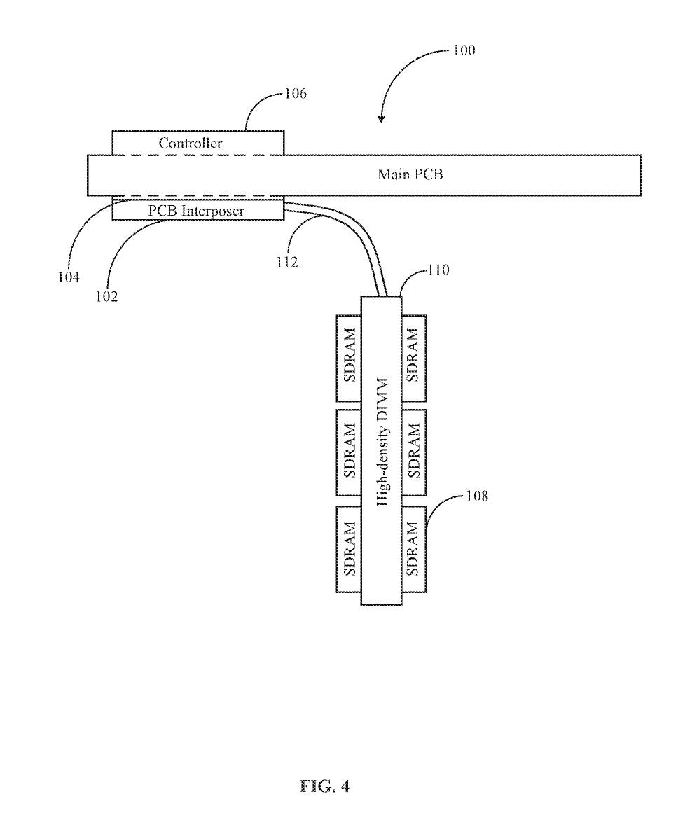

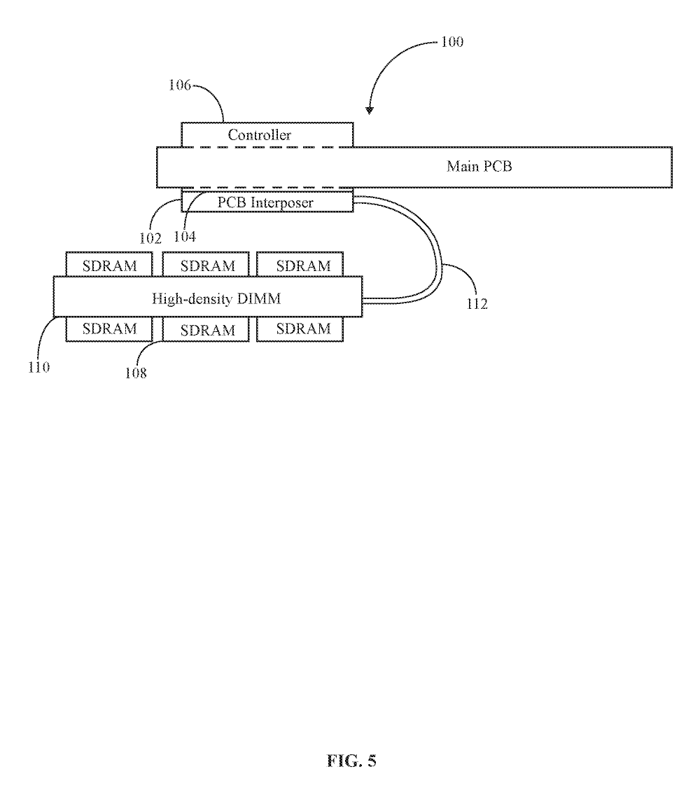

FIG. 4 is a schematic diagram showing the present flexible high-density memory module 100 for use with the electronic computing devices, according to an alternate embodiment of the present disclosure. The flexible substrate 112 or the flexible printed circuit board connecting the first rigid printed circuit board or the first substrate 104 supporting the interposer 102 and the controller 106 and the second rigid printed circuit board or the second substrate 110 supporting the SDRAM modules 108 enables the circuit designers to achieve different configurations with the present flexible high-density memory module 100. FIG. 3 disclose a parallel arrangement of the second rigid printed circuit board or the second substrate 110 supporting the SDRAM modules 108 above the main rigid printed circuit board, whereas FIG. 4 disclose the arrangement of the second rigid printed circuit board or the second substrate 110 supporting the SDRAM modules 108 at right angles to the first substrate 104 supporting the interposer 102 and the controller 106. In the arrangement disclosed in FIG. 4, the flexible substrate 112 is formed with a bend angle at around 90 degrees and the second substrate 110 supporting the SDRAM modules 108 is kept perpendicular to the main rigid printed circuit board of the electronic computing device. In an alternate embodiment of the present invention, as in FIG. 5, the flexible substrate 112 is formed with a bend angle at around 180 degrees and the second substrate 110 supporting the SDRAM modules 108 is kept parallel to the main rigid printed circuit board of the electronic computing device. In all the above types of arrangements, the second substrate 110 supporting the SDRAM modules 108 is flexibly attached to the processor interconnects provided on the main rigid printed circuit board of the electronic computing device. In all the above arrangements, the SDRAM modules 108 are placed on the second substrate 110 or the second rigid printed circuit board according to a memory-down architecture to form a high-density dual in-line memory module. However, the present flexible high-density memory module 100 supports other types of memory architectures as the second substrate 110 or the second rigid printed circuit board is kept away from the main rigid printed circuit board of the electronic computing device. The resulting design of the main rigid printed circuit board of the electronic computing device with separate placement of the SDRAM modules 108 in the present flexible high-density memory module 100 allows the designers to utilize the space, which normally being used for placing the SDRAM modules 108, for better routing of SERDES channels such as the Ethernet 40G, SATA, PCIE-gen3/4, HDMI, etc. Furthermore, the present flexible high-density memory module 100 enables the designers to come up with better thermal design of the main rigid printed circuit board of the electronic computing device. In addition, with proper selection of the bend angle and bend radii of the flexible substrate 112 connecting the SDRAM modules 108 placed on the second substrate 110 and the interposer 102 and the controller 106 supported on the first substrate 104, better signal transmission between the SDRAM modules 108 and the processor is achieved.

According to a preferred embodiment, a surface area of the first substrate 104 supporting the interposer 102 and the controller 106 is considerably smaller than the surface area of a conventional high-density dual in-line memory module (DIMM) 20 used in the prior arts. This allows the circuit designers and fabricators to design and fabricate the main rigid printed circuit board of the electronic computing devices with a minimal slot area for accommodating the present flexible high-density memory module 100 of desired capacity. The present flexible high-density memory module 100 enables the designers to save 30% or more surface area on the main rigid printed circuit board of the electronic computing devices compared to the conventional design of the main rigid printed circuit board with the conventional memory-down configuration of the high-density dual in-line memory modules (DIMM) supported on the slots provided on the main rigid printed circuit board. The additional real-estate space saved on the main rigid printed circuit board of the electronic computing devices, by using the present flexible high-density memory module 100, is utilized for the efficient design and layout of the conductive traces of the SERDES channels on the main rigid printed circuit board of the electronic computing devices. The efficient utilization of the surface area of the main rigid printed circuit board of the electronic computing devices utilizing the present flexible high-density memory modules 100 enables cost optimization on the main rigid PCB. The present flexible high-density memory modules 100 further allows the designers to design an efficient, compact main rigid printed circuit board of the electronic computing devices with an heat management system, which further improves the performance and overall operating life of the electronic computing devices.

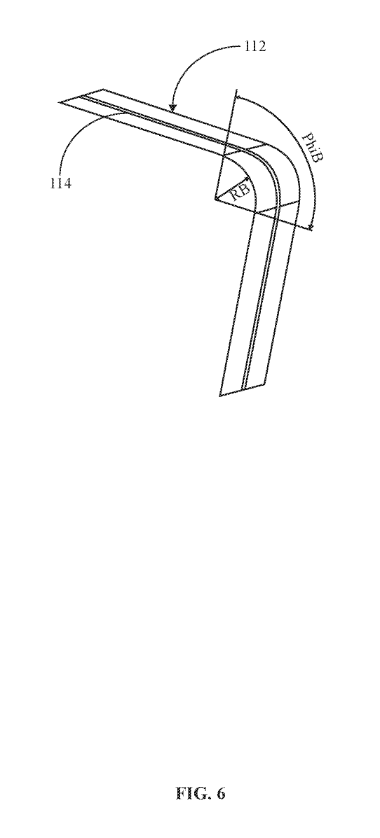

FIG. 6 illustrates a microstrip test structure of the flexible substrate 112 associated with the present flexible high-density memory module 100 to analyze the effect of bend angle and bend radius of the flexible substrate 112 on signal integrity and radiated emission from the present flexible high-density memory module 100, according to an embodiment of the present disclosure. The bending of the flexible substrate 112 connecting the SDRAM modules 108 placed on the second substrate 110 and the interposer 102 and the controller 106 supported on the first substrate 104, in some instances, affects the signal integrity and radiation emission. The present analysis on the effects of the signal integrity and radiation emission due to the bend angle (PhiB) and bend radius (RB) of the flexible substrate 112 is performed by considering microstrip routing method for the conductive traces within the flexible substrate 112. As the microstrip routing deliver the worst performance in terms of both signal integrity and radiation emission, the actual performance of the flexible substrate 112 is considered better than the present analysis results. The bending of the flexible substrate 112 is simulated using a geometric multilayer bending feature in a 3D modeler, which uses flat layout and automatically stretches the metal and dielectric layers in such a way that co-located points in the flat layout remain co-located, without considering the mechanical characteristics on the metal and dielectric layers due to bending. The controller 106 supported on the first substrate 104 communicates with the SDRAM modules 108 supported on the second substrate 110 through the conductive traces, bend at a certain bending angle with a certain bend radii, supported on the flexible substrate 112.

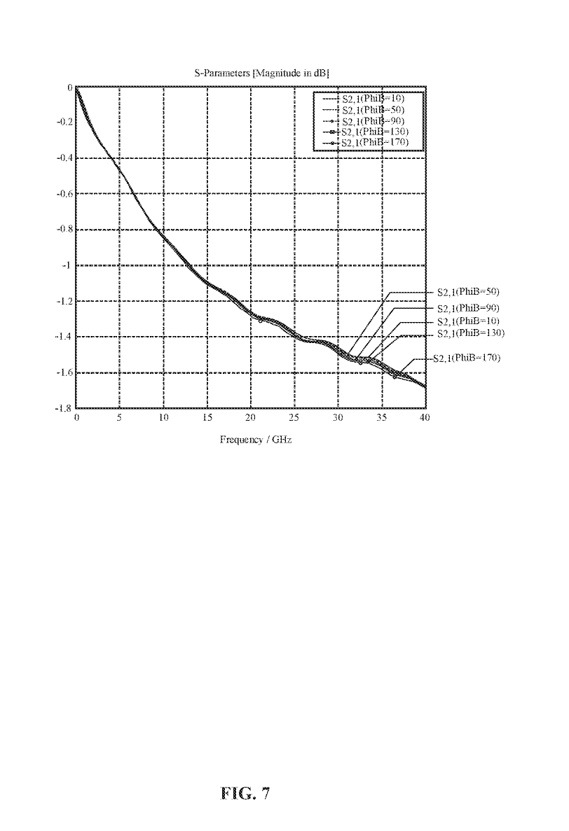

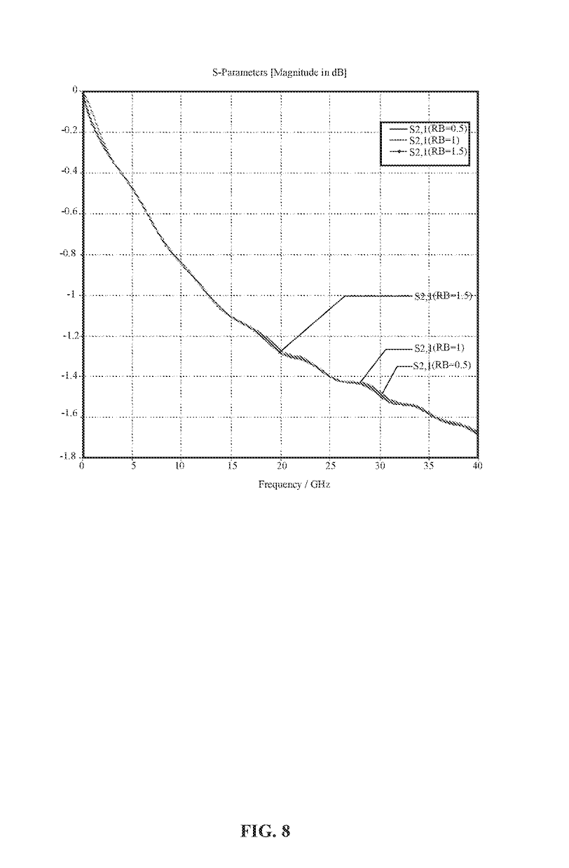

FIG. 7 is a graph showing an insertion loss of the present flexible high-density memory module 100 for different bend angles of the flexible substrate 112 under a constant bend radius, and according to an embodiment of the present invention. The insertion loss of the present flexible high-density memory module 100 is determined with bend angles 10, 50, 90, 130 and 170 degrees with constant bend radii. From the graph, it is clear that the bend angle doesn't have a significant influence on the insertion loss of the flexible substrate 112 in form of a bent microstrip. Similarly, FIG. 8 is a graph showing an insertion loss of the present flexible high-density memory module 100 for different bend radii of the flexible substrate 112 under a constant bend angle, and according to an embodiment of the present invention. From the graph, it is clear that the bend radii do not have a significant influence on the insertion loss of the flexible substrate 112 in form of the bent microstrip.

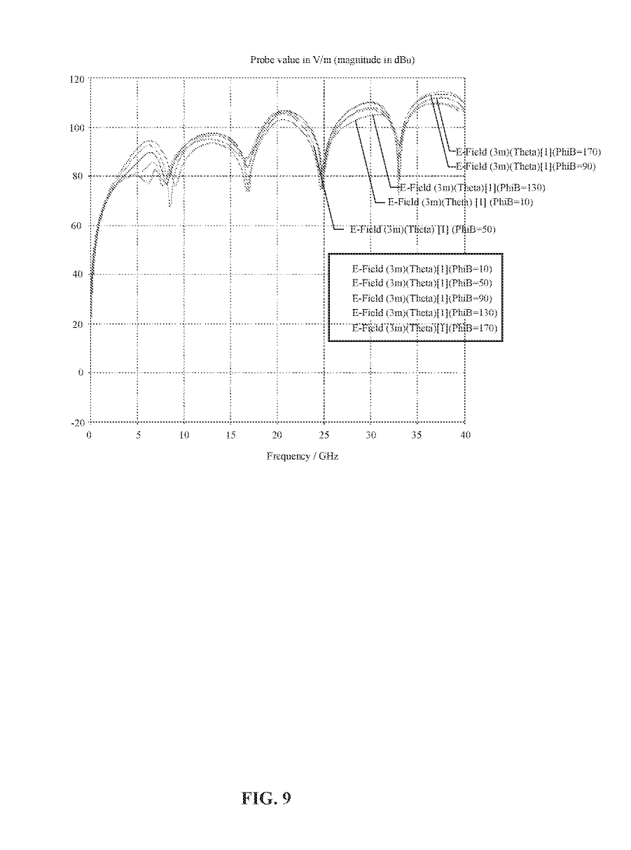

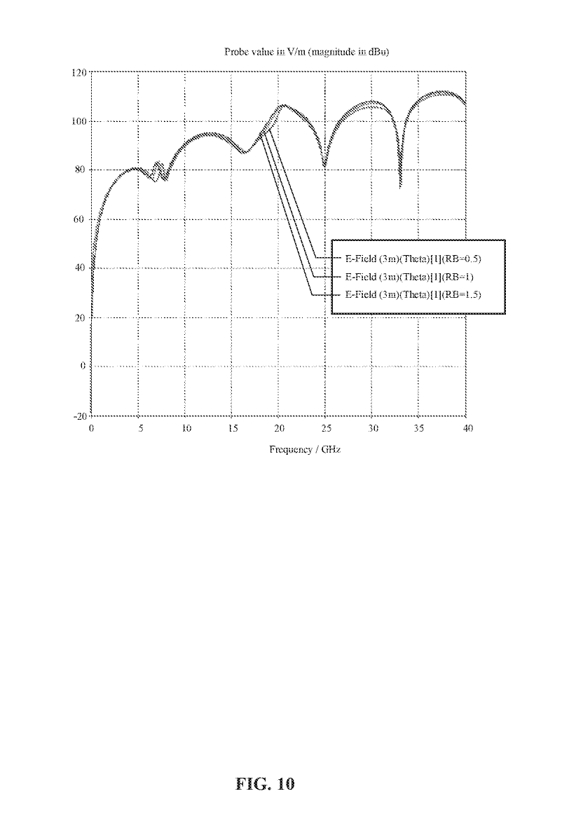

FIG. 9 is a graph showing a normalized radiated emission at a distance of at least 3 meters from the bend microstrip of the flexible substrate 112 with different bend angles, according to an embodiment of the present invention. In order to analyze the emission from the microstrip flexible substrate 112, a farfield probe is kept at 3 m distance away from the bend and the absolute electric field strength in that location is recorded. FIG. 10 is another graph showing the normalized radiated emission at a distance of 3 meters for different bend radii of the flexible substrate 112, according to an embodiment of the present invention. The analysis assumes a 1 W excitation at every frequency and a perfect termination of the trace at both ends. The measurements were carried out with bend angles of 10, 50, 90, 130 and 170 degrees with constant bend radii as in FIG. 9 and with bend radii of 0.5, 1.0 and 1.5 with constant bend angle, as in FIG. 10. The variation in bend angles with constant radii shows an effect on the emission levels from the microstrip flexible substrate 112. From the graph shown in FIG. 9, it is clear that larger bend angles result in lower emission levels. As the bend angle increases, the radiated power from the microstrip flexible substrate 112 is distributed over a larger solid angle, which reduces the radiation emission towards a particular direction. Similarly, from the graph shown in FIG. 10, it is clear that the bed radius doesn't have a significant influence on the radiation emission from the microstrip flexible substrate 112. Thus, from the above analysis on the effect of bend radius and the bend angle on the emission levels and insertion loss of the microstrip flexible substrate 112, the effect of the bending will be less of a concern for the flexible high-density memory module 100. However, the emission levels and insertion loss of the microstrip flexible substrate 112 depends on the material of the microstrip flexible substrate 112 and routing constraints.

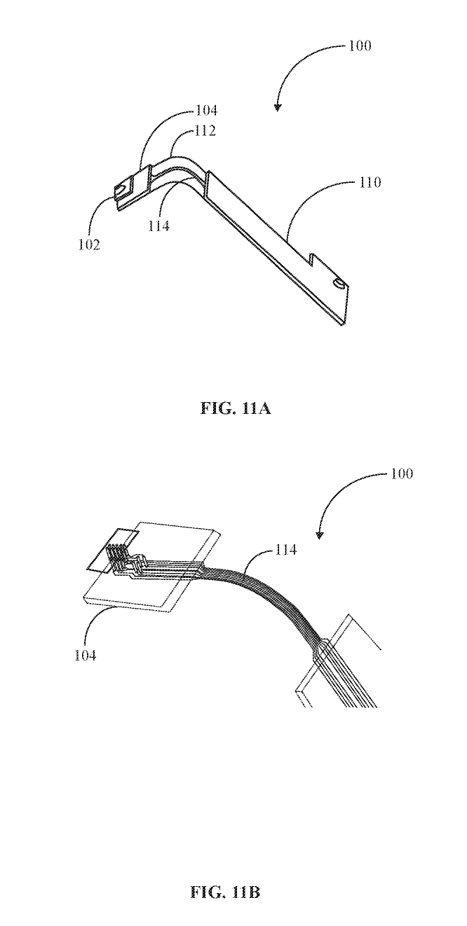

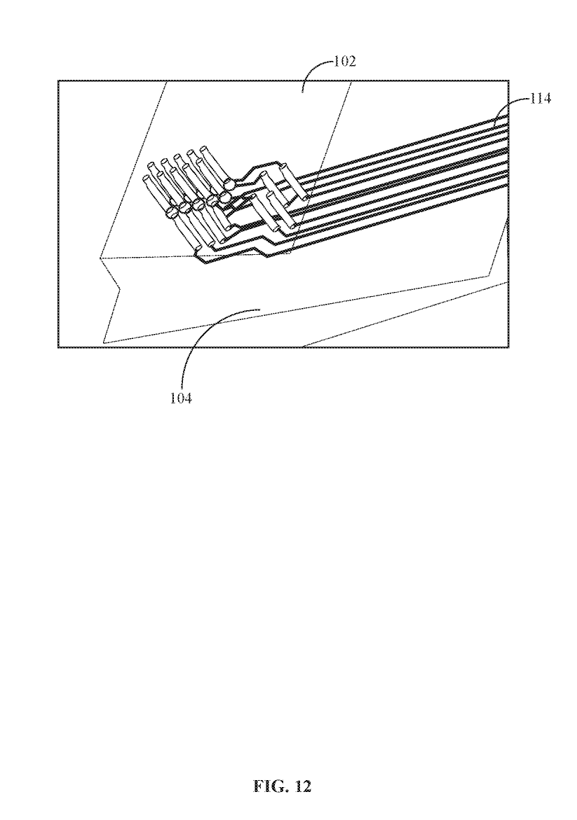

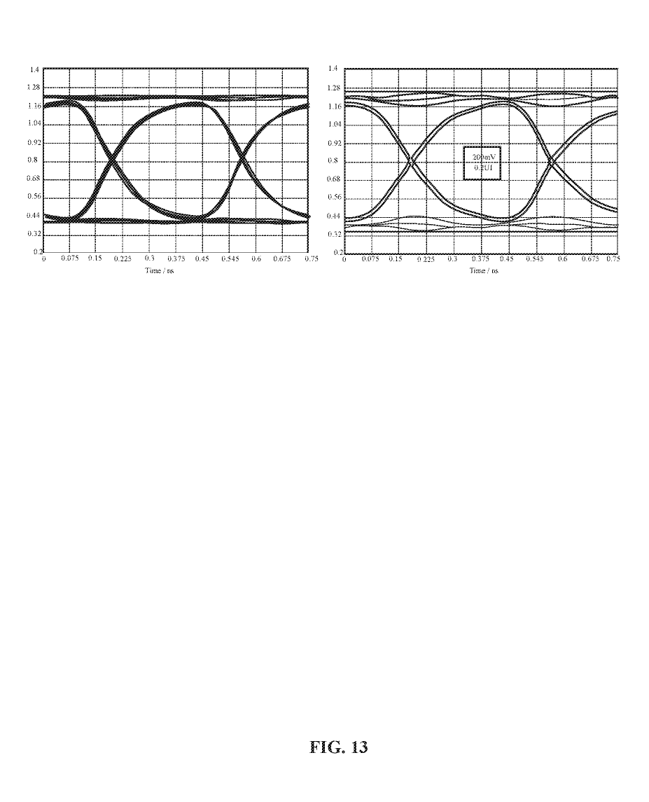

Further, a high-fidelity case study of a realistic model of the present flexible high-density memory module 100 is performed and its performance is compared to conventional memory-down design with the same memory density, according to an exemplary analysis of the present invention. FIG. 11A shows a three-dimensional model of the present flexible high-density memory module 100, according to a preferred embodiment of the present invention. FIG. 12 shows a three-dimensional model showing a breakout region of the main rigid printed circuit board and the interposer 102 of the flexible high-density memory module 100, according to a preferred embodiment of the present invention. The 3D model of the present flexible high-density memory module 100 shown in FIG. 11A and FIG. 12 consists of the entire channel in one single model. Further in FIG. 11B, the first substrate 104 supporting the interposer 102 and the controller 106, solder balls, the interposer 102, the flexible PCB or the flexible substrate 112 and the DIMM PCB or the second substrate 110 supporting the SDRAM modules 108 are represented without simplifications in full 3D detail.

In certain instances, the flexible section or the flexible PCB or the flexible substrate 112 is about 24 mm long with the bent section taking up about 15 mm. In certain instances, the flexible substrate 112 employs two metal layers such as the signal layer and the ground layer in the flexible region. As can be clearly seen in FIG. 11B, in the bent section, the signal nets are routed with the smaller distance to accommodate all signal nets on a single layer. In order to perform a realistic model analysis of the present flexible high-density memory module 100, the one-byte lane of the DQ bus to the SDRAM chip 108, which is the furthest away from the controller 106 is considered, thus giving a worst-case performance obtained with the present flexible substrate 112. Further, the S-parameters are calculated using the TLM solver in CST Studio Suite™, which gives a good broadband performance and allows for an accurate conformal meshing of both rigid and flexible PCBs without a large effect of mesh bleeding.

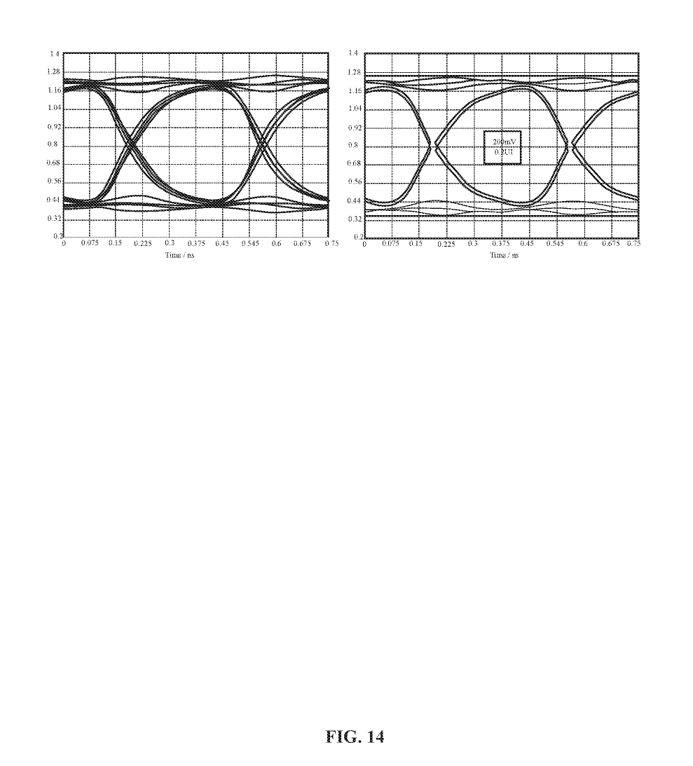

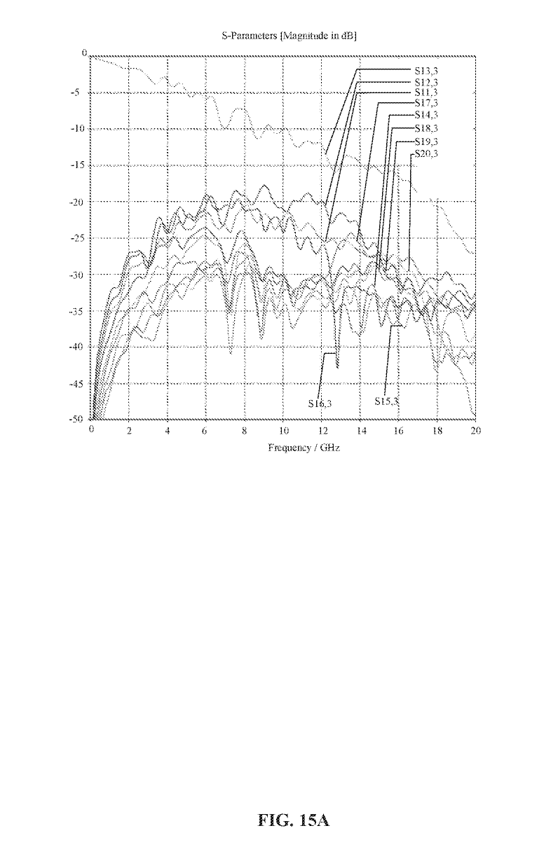

FIG. 13 shows a worst-case eye diagram and BER contour for one victim on the Flex-DIMM or the present flexible high-density memory module 100 with SDRAM modules 108 at 2666 MT/s, without considering the crosstalk, according to an embodiment of the present invention. FIG. 14 shows a worst-case eye diagram and BER contour for one victim on a reference design, which uses a conventional memory-down configuration with the same memory density, at 2666 MT/s, without considering the crosstalk, according to an embodiment of the present invention. When the worst-case eye diagram and BER contour for one victim on the Flex-DIMM or the present flexible high-density memory module 100, shown in FIG. 13, is compared with the same results, shown in FIG. 14, of the reference design that uses a conventional memory-down configuration with the same memory density, it is clear that the eye opening is nearly identical between the Flex-DIMM or the present flexible high-density memory module 100 and the reference design.

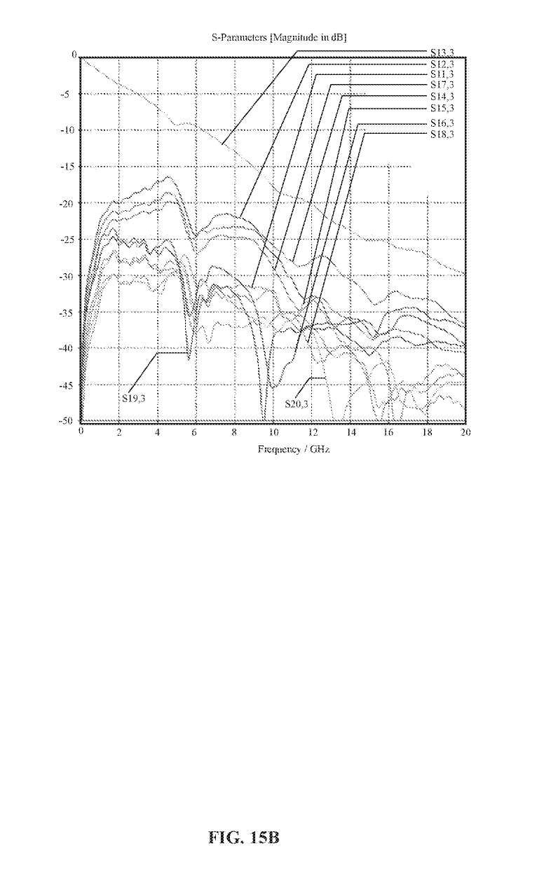

FIG. 15A shows an insertion loss and far-end crosstalk for one bit of the reference design and FIG. 15B shows the same bit on the flex interposer 102 of the present flexible high-density memory module 100, according to an embodiment of the present invention. The present flexible high-density memory module 100 with SDRAM modules 108 forming the high density DIMM arrangement is capable of offering transfer rates up to 2666 MT/s and more during normal operation. Higher transfer rates using the present flexible high-density memory module 100 is achieved by reducing the cross-talk in the flexible PCB region or the flexible substrate 112 forming electrical connection between the interposer 102 supported on the first substrate 104 and the SDRAM modules 108 supported on the second substrate 110. The cross-talk in the flexible PCB region or the flexible substrate 112 is achieved using multiple layers according to one or more embodiment of the present invention. Utilization of three layers or more in the flexible PCB region or the flexible substrate 112 provides less cross talk in the stripline routing according to one or more embodiment of the present invention. Further, increasing the layer count in the flexible PCB region or the flexible substrate 112 also allow the designers to increase the separation distance of the signal nets, thus further reducing cross-talk in the present flexible high-density memory module 100.

The present invention further proposes a new design for a variety of electronic computing devices with a single printed circuit board computing system having a processor having a number of processor interconnects supported on a main rigid printed circuit board, a number of conductive paths provided on the main rigid circuit board to enable a number of connections between the processor and a number of different types of components via the processor interconnects and a flexible high density memory module 100. The flexible high density memory module 100 of the present electronic computing devices includes an interposer 102 having a number of interposer interconnects supported on the first substrate 104 configured to form at least one connection with the processor interconnects, at least one controller 106 supported on the first substrate 104, a number of SDRAM modules 108 arranged on a second substrate 110 and a flexible substrate 112 supporting at least one conductive trace having a first end and a second end, each having a number of connectors, for forming an electrical connection between the interposer interconnects and the SDRAM modules 108. The processor communicates with the SDRAM modules 108 through the conductive traces provided on the flexible substrates 112. The flexible high-density memory module 100 is connected to the main rigid printed circuit board using the interposer interconnects supported on the first substrate 104. The first substrate 104 supporting the interposer 102 and the controller 106 is a first rigid printed circuit board, which supports the he interposer 102 and the controller 106 on a same surface and on opposite surfaces. Further, the present flexible high-density memory module 100 can be made as a plug and play memory module that can be attached to the slot provided on the main rigid circuit board of the electronic computing devices.

The flexible substrate 112 of the flexible high-density memory module 100 enables a parallel placement of the SDRAM modules 108 arranged on the second substrate 110 over a plane of the main rigid printed circuit board, or a perpendicular placement of the SDRAM modules 108 arranged on the second substrate 110 over a plane of the main rigid printed circuit board, or an angular placement of the SDRAM modules 108 arranged on the second substrate 110 over a plane of the main rigid printed circuit board. However the arrangement of the second substrate 110 over a plane of the main rigid printed circuit board depends on the mechanical requirements, thermal requirements, spacing requirements and the casing design of the electronic computing devices. Thus the present flexible high-density memory module 100 optimizes a surface area utilization of the main rigid printed circuit board by placing the SDRAM modules 108 on the second substrate 110 over the main rigid printed circuit board. Further the flexible substrate 112, of the flexible high-density memory module 100, connecting the first substrate 104 to the second substrate 110 enables an optimal surface area utilization of the main rigid printed circuit board, an optimal heat dissipation from the SDRAM modules 108 providing an optimal performance of the SDRAM modules 108. The flexible high-density memory module 100 also enables the embedded designers to achieve an optimal routing and improved performance of the SERDES channels associated with the main rigid printed circuit board. Further the SDRAM modules 108 supported on the second substrate 110 can form a number of dual in-line memory modules (DIMM), arranged based on memory-down architecture or any other supported architecture, of desired capacity and capable of operating at a desired frequency. The present flexible high-density memory module 100 is configured to function in form of a plug and play memory channel for the electronic computing devices. The flexible high-density memory module with multi-layered flexible substrate 112 enables optimal performance of the SDRAM modules by preventing cross-talk between the components associated with the main rigid printed circuit board. Further selection of an optimal bend angle and a bend radius of the flexible substrate 112 also assist to achieve an improved performance with the present flexible high-density memory module 100. The flexible substrate 112 further enables optimal performance of the SDRAM modules 108 by providing optimal heat dissipation with the optimal selection of the bend angle and the bend radius.

The present flexible high-density memory module 100 proposes a new architecture replacing the memory down for embedded systems such as SBCs, ADAS and infotainment applications requiring high-density and maximum performance memory channels utilizing DDR4 and LPDDR4 latest technology. The present flexible high-density memory module 100 is capable of being operated as a plug-n-play like the conventional socketed DIMM configuration in the above said embedded computing systems without any mechanical constraints. The present flexible high-density memory module 100 enables the embedded designer to optimize the stackups for the main-PCB and the flexible high-density memory module 100 separately to achieve best performance for both SERDES and the memory channels independently. For example, the embedded designers can optimize the stackup with lower-layer count for the main-PCB for SERDES while separately optimizing the Flex-DIMM stackup 100 for best single-ended data signals. The performance of the present flexible high-density memory module 100 is improved by turning-on the DBI, which is a critical feature in DDR4 and LPDDR4 to reduce x-talk, and by increasing the number of layers on the flexible substrate 112 to enable strip-line routing on the flexible substrate 112, which further reduces the radiated emission. Further the use of the present flexible high-density memory module 100 enables the embedded designers to save at least save 30% of the main-PCB real-estate, which in turn can be used for SERDES channels and promotes the cost optimization between the main-PCB and the present flexible high-density memory module 100.

Further, it should be noted that the steps described in the method of use could be carried out in many different orders according to user preference. The use of “step of” should not be interpreted as “step for”, in the claims herein and is not intended to invoke the provisions of 35 U.S.C. § 112, (6). Upon reading this specification, it should be appreciated that, under appropriate circumstances, considering such issues as design preference, user preferences, marketing preferences, cost, technological advances, etc., other methods of use arrangements, elimination or addition of certain steps, including or excluding certain maintenance steps, etc., may be sufficient.

The foregoing description of the preferred embodiment of the present invention has been presented for the purpose of illustration and description. It is not intended to be exhaustive or to limit the invention to the precise form disclosed. Many modifications and variations are possible in light of the above teachings. It is intended that the scope of the present invention not be limited by this detailed description, but by the claims and the equivalents to the claims appended hereto.

What is claimed is new and desired to be protected by Letters Patent is set forth in the appended claims:

1. A flexible high density memory module for use with a plurality of electronic computing devices comprising:
a) at least one interposer having a plurality of interposer interconnects supported on a first substrate, the plurality of interposer interconnects being configured to form at least one connection with a plurality of processor interconnects supported on a main rigid printed circuit board;
b) at least one controller supported on the first substrate;
c) a plurality of SDRAM modules operably arranged on a second substrate; and
d) at least one conductive trace supported on a flexible substrate having a first end and a second end, each having a plurality of connectors, for forming an electrical connection between the interposer supported on the first substrate and the plurality of SDRAM modules supported on the second substrate;
whereby the controller and the interposer supported on the first substrate is configured to electrically connect to the plurality of processor interconnects supported on the main rigid printed circuit board of the electronic computing device to provide a plurality of plug and play, flexible, high density memory channels of desired capacities utilizing the plurality of SDRAM modules supported on the second substrate.

2. The flexible high-density memory module of claim 1, wherein the first substrate supporting the interposer and the controller is a first rigid printed circuit board.

3. The flexible high-density memory module of claim 2, wherein the interposer and the controller are supported on one side of the first rigid printed circuit board.

4. The flexible high-density memory module of claim 2, wherein the interposer and the controller are supported on opposite sides of the first rigid printed circuit board.

5. The flexible high-density memory module of claim 1, wherein the second substrate supporting the plurality of SDRAM modules is a second rigid printed circuit board, wherein the second rigid printed circuit board is provided with a large surface area compared to the first rigid printed circuit board.

6. The flexible high-density memory module of claim 1, wherein the flexible substrate supporting the plurality of conductive traces is a flexible printed circuit board,
wherein the plurality of connectors at the first end of the conductive traces connects to the interposer and the controller supported on the first substrate,
wherein the plurality of connectors at the second end of the conductive traces connects to the plurality of SDRAM modules supported on the second substrate.

7. The flexible high-density memory module of claim 1, wherein the controller supported on the first substrate is configured to communicate with the plurality of SDRAM modules supported on the second substrate through the conductive traces supported on the flexible substrate.

8. The flexible high-density memory module of claim 1, wherein the plurality of SDRAM modules supported on the second substrate forms a plurality of dual in-line memory modules (DIMM) of desired capacity capable of operating at a desired frequency.

9. The flexible high-density memory module of claim 1, is configured to function in form of a plurality of plug and play memory channels for the plurality of electronic computing devices.

10. The flexible high-density memory module of claim 1, wherein the flexible substrate enables a parallel placement of the plurality of SDRAM modules over the main rigid printed circuit board of the electronic computing device enabling optimal utilization of a surface area of the main rigid printed circuit board.

11. The flexible high-density memory module of claim 1, wherein the flexible substrate enables a perpendicular placement of the plurality of SDRAM modules over the main rigid printed circuit board of the electronic computing device enabling optimal utilization of the surface area of the main rigid printed circuit board.

12. The flexible high-density memory module of claim 1, wherein the flexible substrate enables an angular placement of the plurality of SDRAM modules over the main rigid printed circuit board of the electronic computing device enabling optimal utilization of the surface area of the main rigid printed circuit board.

13. The flexible high-density memory module of claim 1, wherein the flexible substrate with a plurality of layers enables optimal performance of the plurality of SDRAM modules by preventing cross-talk between a plurality of components associated with the main rigid printed circuit board.

14. The flexible high-density memory module of claim 14, wherein the flexible substrate enables optimal performance of the plurality of SDRAM modules by providing optimal heat dissipation with the optimal selection of the bend angle and the bend radius.

15. The flexible high-density memory module of claim 1, enables optimal routing and performance of a plurality of SERDES channels associated with the main rigid printed circuit board of the electronic computing devices by supporting the SDRAM modules on the second substrate.

16. An electronic computing device, comprising:
a) a processor having a plurality of processor interconnects supported on a main rigid printed circuit board;
b) a plurality of conductive paths provided on the main rigid circuit board to enable a plurality of connections between the processor and a plurality of components via the plurality of processor interconnects; and
c) a flexible high density memory module comprising:
i. at least one interposer having a plurality of interposer interconnects supported on a first substrate configured to form at least one connection with the plurality of processor interconnects;
ii. at least one controller supported on the first substrate;
iii. a plurality of SDRAM modules arranged on a second substrate; and
iv. a flexible substrate supporting at least one conductive trace having a first end and a second end, each having a plurality of connectors, for forming an electrical connection between the interposer interconnects and the plurality of SDRAM modules;
whereby the processor communicates with the plurality of SDRAM modules through the conductive traces provided on the flexible substrates.

17. The electronic computing device of claim 16, wherein the flexible high density memory module is connected to the main rigid printed circuit board using the plurality of interposer interconnects supported on the first substrate.

18. The electronic computing device of claim 16, wherein the first substrate supporting the interposer and the controller is a first rigid printed circuit board,
wherein the first rigid printed circuit board is configured to support the interposer and the controller on a same surface and on opposite surfaces.

19. The electronic computing device of claim 16, wherein the flexible high-density memory module is a plug and play memory module.

20. The electronic computing device of claim 16, wherein the flexible substrate of the flexible high-density memory module enables:
a parallel placement of the plurality of SDRAM modules arranged on the second substrate over a plane of the main rigid printed circuit board;
a perpendicular placement of the plurality of SDRAM modules arranged on the second substrate over a plane of the main rigid printed circuit board; and
an angular placement of the plurality of SDRAM modules arranged on the second substrate over a plane of the main rigid printed circuit board;
wherein the flexible high-density memory module optimizes a surface area utilization of the main rigid printed circuit board by placing the plurality of SDRAM modules arranged on the second substrate over the main rigid printed circuit board;
wherein the flexible substrate, of the flexible high-density memory module, connecting the first substrate to the second substrate enables:
an optimal surface area utilization of the main rigid printed circuit board;
an optimal heat dissipation from the plurality of SDRAM modules;
an optimal performance of the plurality of SDRAM modules; and
an optimal routing and performance of a plurality of SERDES channels associated with the main rigid printed circuit board.
